(19) United States
(12) Patent Application Publication
(10) Pub. No.: US 2002/0187603 A1
(43) Pub. Date: Dec. 12, 2002

(54) Method for fabricating recessed lightly doped drain field effect transistors

(75) Inventor: Horng-Huei Tseng, Hsinchu (TW)

Correspondence Address: Richard E. Fichter, BACON & THOMAS, PLLC, Fourth Floor, 625 Slaters Lane, Alexandria, VA, 22314, US

(73) Assignee: Vanguard International Semiconductor Corporation, Hsinchu (TW)

(21) Appl. No.: 10/211,543

(22) Filed: Aug. 5, 2002

Related U.S. Application Data
(63) Continuation-in-part of application No. 09/850,096, filed on May 8, 2001.

(51) Int. Cl. H01L 21/8238

(52) U.S. Cl. 438/212

(57) ABSTRACT

The present invention provides a method for fabricating a recessed field-effect transistor, comprising steps of: providing a silicon substrate; forming a first dielectric layer on said substrate; patterning said first dielectric layer so as to form a window; forming a gate dielectric layer on said substrate inside said window; forming a poly-silicon layer covering said gate dielectric layer and said first dielectric layer; etching back said poly-silicon layer after said first dielectric layer is exposed, leaving poly-silicon in said window; forming a metal layer covering said poly-silicon layer and said first dielectric layer; removing said metal layer outside said window; removing said first dielectric layer on said substrate; and heavily doping ions so as to form heavily doped regions.

### CROSS REFERENCE TO RELATED APPLICATION

This application is a continuation-in-part of U.S. patent application Ser. No. 09/850,096 filed Aug. 5, 2001, entitled “METHOD FOR FABRICATING RECESSED LIGHTLY DOPED DRAIN FIELD-EFFECT TRANSISTOR” That application is incorporated herein by reference in its entirety for all purposes.

### BACKGROUND OF THE INVENTION

1. Field of the Invention

The present invention generally relates to a method for fabricating a recessed field-effect transistor and, more particularly, to a method for fabricating a recessed field-effect transistor having a stack gate electrode so as to achieve a better work function.

2. Description of the Prior Art

The metal-oxide-semiconductor field-effect transistor (MOSFET) has now become the most important device in very/ultra large scale integrated circuits (VLSIs/ULSIs). In addition to the MOS structure, there are provided a source electrode, a drain electrode and a gate electrode on the top of the MOS structure. Complementary MOS (CMOS) circuits have been widely used in logic applications such as microprocessors, micro-controllers, and so forth.

However, with response to the requirement of simplified processing and improved reliability for the industry, a method for fabricating field-effect transistors has been disclosed. FIG. 1A to FIG. 1E are schematic diagrams illustrating the steps of a method for fabricating a field-effect transistor. As shown in FIG. 1A, a gate oxide layer 20 is formed on a silicon substrate 10 and then a poly-silicon layer 30 and a conductor layer 40 are deposited and defined by photolithography and etching, wherein the conductor layer 40 is composed of conducting materials such as silicide and metal to function as a gate electrode. The main difference from the other prior arts is that a doped dielectric layer 50 is deposited on the conductor layer 40 and the gate oxide layer 20. The doped dielectric layer 50 is doped with the required p-type or n-type dopants, as shown in FIG. 1B.

Then, the doped dielectric layer 50 is etched back to form spacers 501, more particularly, doped spacers, as shown in FIG. 1C.

During the subsequent thermal process, the impurities in the spacers 501 may thermally diffuse into the substrate 10 and form lightly doped regions 60, as shown in FIG. 1D.

Finally, a heavily doped region 70 is formed by heavily doping ions into the substrate so as to complete a field-effect transistor, as shown in FIG. 1E.

Even though the fore-mentioned method is more progressive than the conventional ones, however, there still exists a problem in that it is more difficult to etch metal than non-metal materials.

In view of this, the present invention discloses a method for fabricating a novel recessed field-effect transistor, wherein a stack gate is provided so as to obtain a better work function. In this method, the process reliability can be improved because the poly-silicon instead of metal is etched.

### SUMMARY OF THE INVENTION

It is the primary object of the present invention to provide a method for fabricating a recessed field-effect transistor, wherein a stack gate is provided so as to obtain a better work function.

It is another object of the present invention to provide a method for fabricating a recessed field-effect transistor, wherein the process reliability can be improved because poly-silicon instead of metal is etched.

In order to achieve the foregoing objects, the present invention provides a method for fabricating a recessed field-effect transistor, comprising steps of: providing a silicon substrate; forming a first dielectric layer on said substrate; patterning said first dielectric layer so as to form a window; forming a gate dielectric layer on said substrate inside said window; forming a poly-silicon layer covering said gate dielectric layer and said first dielectric layer; etching back said poly-silicon layer after said first dielectric layer is exposed, leaving poly-silicon in said window; forming a metal layer covering said poly-silicon layer and said first dielectric layer; removing said metal layer outside said window; removing said first dielectric layer on said substrate; and heavily doping ions so as to form heavily doped regions.

Other and further features, advantages and benefits of the invention will become apparent in the following description taken in conjunction with the following drawings. It is to be understood that the foregoing general description and following detailed description are exemplary and explanatory but are not to be restrictive of the invention. The accompanying drawings are incorporated in and constitute a part of this application and, together with the description, serve to explain the principles of the invention in general terms. Like numerals refer to like parts throughout the disclosure.

### BRIEF DESCRIPTION OF THE DRAWINGS

The objects, spirits and advantages of the preferred embodiments of the present invention will be readily understood by the accompanying drawings and detailed descriptions, wherein:

FIG. 1A to FIG. 1E are schematic diagrams illustrating the steps of a method for fabricating a field-effect transistor in the prior art;

FIG. 2A to FIG. 2F are schematic diagrams illustrating the steps of a method for fabricating a recessed field-effect transistor in accordance with the first and the second embodiments of the present invention; and

FIG. 3A to FIG. 3F are schematic diagrams illustrating the steps of a method for fabricating a recessed field-effect transistor in accordance with the third and the fourth embodiments of the present invention.

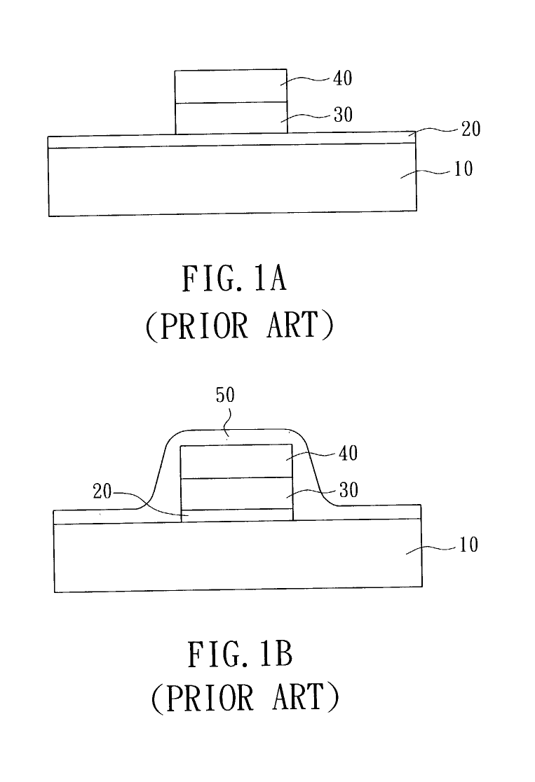

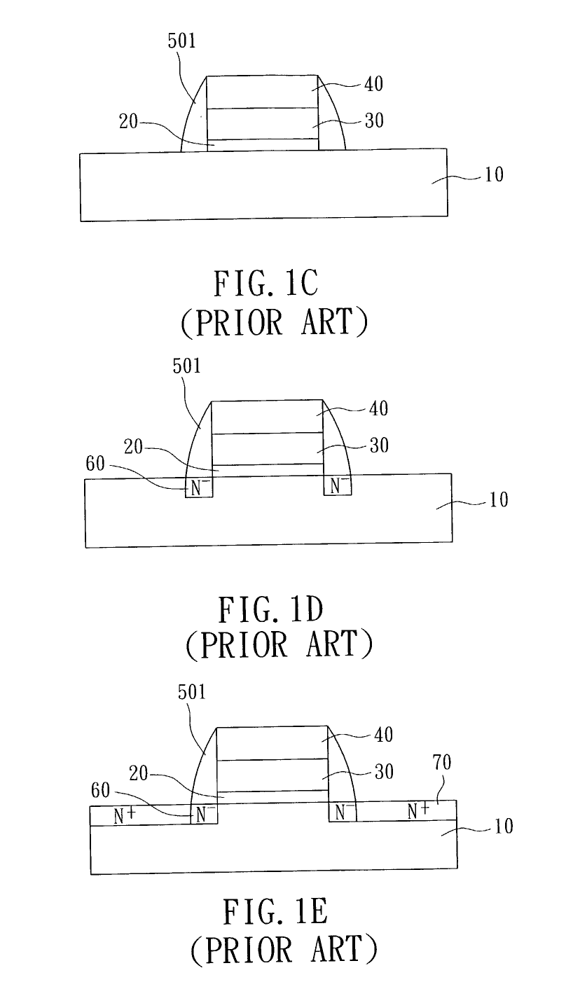

### DETAILED DESCRIPTION OF THE INVENTION

The present invention providing a method for fabricating a recessed field-effect transistor can be exemplified by the preferred embodiments as described hereinafter.

[The First Embodiment]

The present invention is described with reference to a first embodiment wherein a recessed field-effect transistor is formed on a p-type substrate.

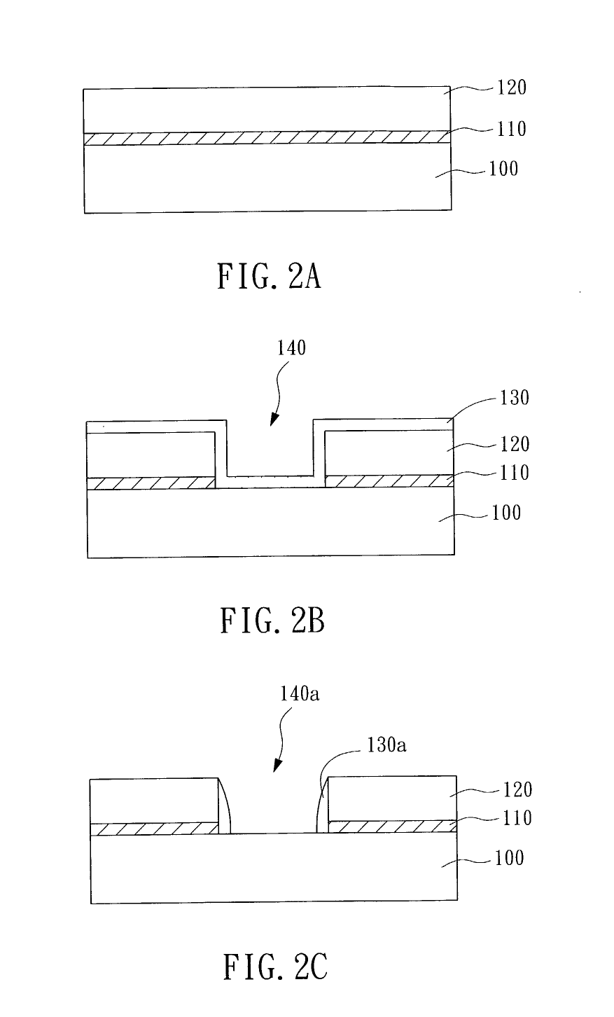

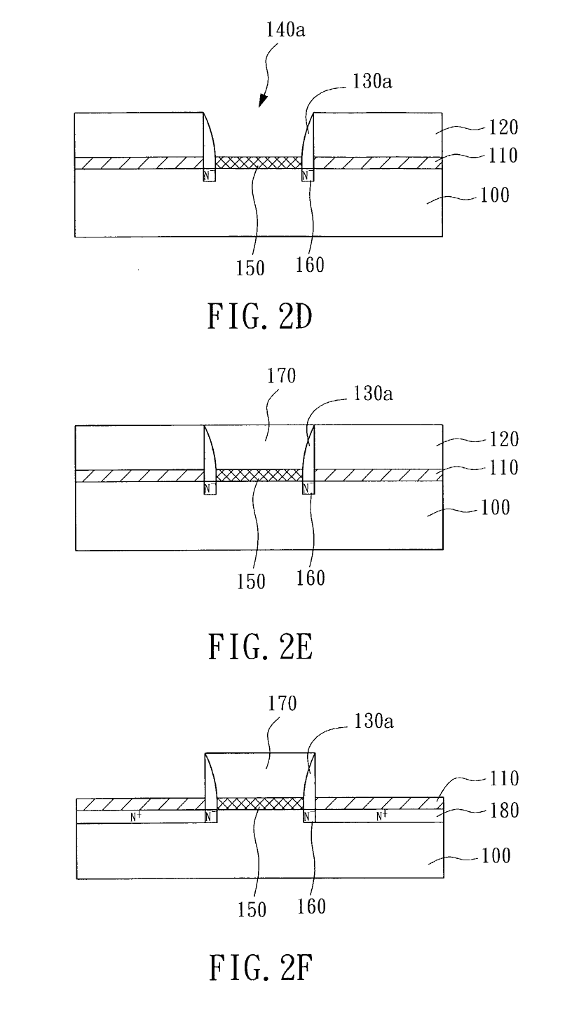

Please refer to FIG. 2A, wherein there is provided a p-type silicon substrate 100. On the p-type silicon substrate 100, a sacrificial layer 110 and a first dielectric layer 120 are formed. The sacrificial layer 110 can be formed by forming a silicon oxide layer of 50˜500 Å in thickness on the silicon substrate 100 by thermal oxidation. The first dielectric layer 120 can be formed by depositing a dielectric layer by chemical vapor-phase deposition (CVD).

The present invention is characterized in that the sacrificial layer 110 and the first dielectric layer 120 are patterned so as to form a window 140, wherein the window 140 is 0.05˜0.5 μm in width. Later, as shown in FIG. 2B, a doped dielectric layer 130 is deposited, and the doped dielectric layer 130 is an n-type doped dielectric layer, wherein the dopant is solid-state As, solid-state P, or AsH₃ gas.

Moreover, as shown in FIG. 2C, the doped dielectric layer 130 is etched back so as to form doped spacers 130a in the window 140a.

Thermal oxidation is then performed to form a gate dielectric layer 150. In such a high temperature environment, the doped spacer 130a functions as a dopant source and lightly doped regions 160 are thus formed during the process of forming the gate dielectric layer 150, as shown in FIG. 2D.

Please further refer to FIG. 2E, a conductor layer 170 is deposited and fills the window 140a, wherein the conductor layer 170 is composed of one of poly-silicon, silicide and metal. Planarization is performed by removing the residual conductor 170 outside the window 140a by chemical mechanical polishing (CMP).

Finally, the first dielectric layer 120 is removed and then the n-type dopant is heavily doped into the substrate 100 so as to form heavily doped regions 180 on which are formed the source and the drain, as shown in FIG. 2F. In this manner, a recessed field-effect transistor is completed.

[The Second Embodiment]

Similarly, the present invention is described with reference to a second embodiment wherein a recessed field-effect transistor is formed on an n-type substrate. The present embodiment uses the same symbols as in the first embodiment.

Please refer to FIG. 2A, wherein there is provided an n-type silicon substrate 100. On the n-type silicon substrate 100, a sacrificial layer 110 and a first dielectric layer 120 are formed. The sacrificial layer 110 can be formed by forming a silicon oxide layer of 50˜500 Å in thickness on the silicon substrate 100 by thermal oxidation. The first dielectric layer 120 can be formed by depositing a dielectric layer by chemical vapor-phase deposition (CVD).

The present invention is characterized in that the sacrificial layer 110 and the first dielectric layer 120 are patterned so as to form a window 140, wherein the window 140 is 0.05˜0.5 μm in width. Later, as shown in FIG. 2B, a doped dielectric layer 130 is deposited, and the doped dielectric layer 130 is an p-type doped dielectric layer, wherein the dopant is BF₃.

Moreover, as shown in FIG. 2C, the doped dielectric layer 130 is etched back so as to form doped spacers 130a in the window 140a.

Thermal oxidation is then performed to form a gate dielectric layer 150. In such a high temperature environment, the doped spacer 130a functions as a dopant source and lightly doped regions 160 are thus formed during the process of forming the gate dielectric layer 150, as shown in FIG. 2D.

Please further refer to FIG. 2E, a conductor layer 170 is deposited and fills the window 140a, wherein the conductor layer 170 is composed of one of poly-silicon, suicide and metal. Planarization is performed by removing the residual conductor 170 outside the window 140a by chemical mechanical polishing (CMP).

Finally, the first dielectric layer 120 is removed and then the n-type dopant is heavily doped into the substrate 100 so as to form heavily doped regions 180 on which are formed the source and the drain, as shown in FIG. 2F. In this manner, a recessed field-effect transistor is completed.

[The Third Embodiment]

The present invention is described with reference to a third embodiment wherein a recessed field-effect transistor is formed on a p-type substrate.

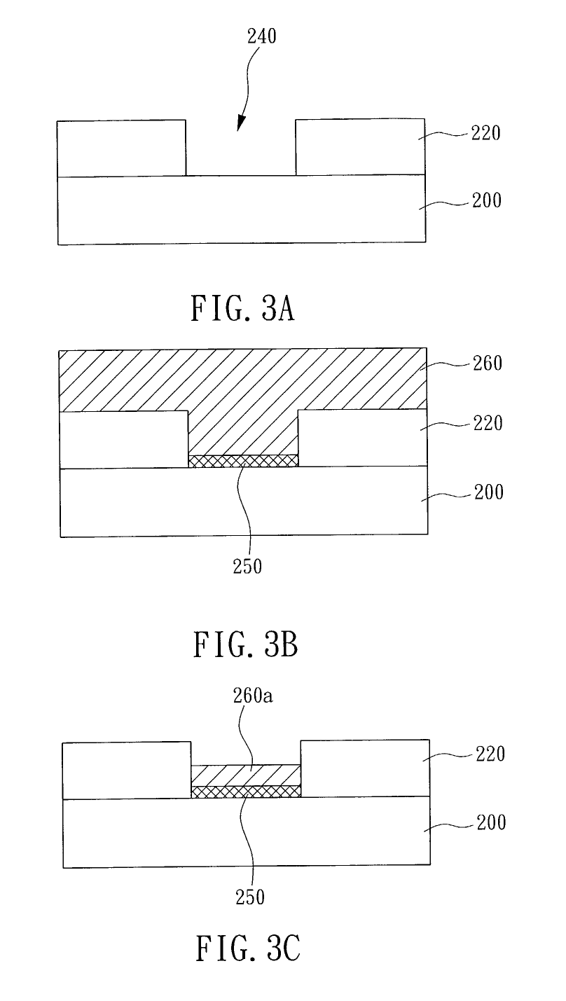

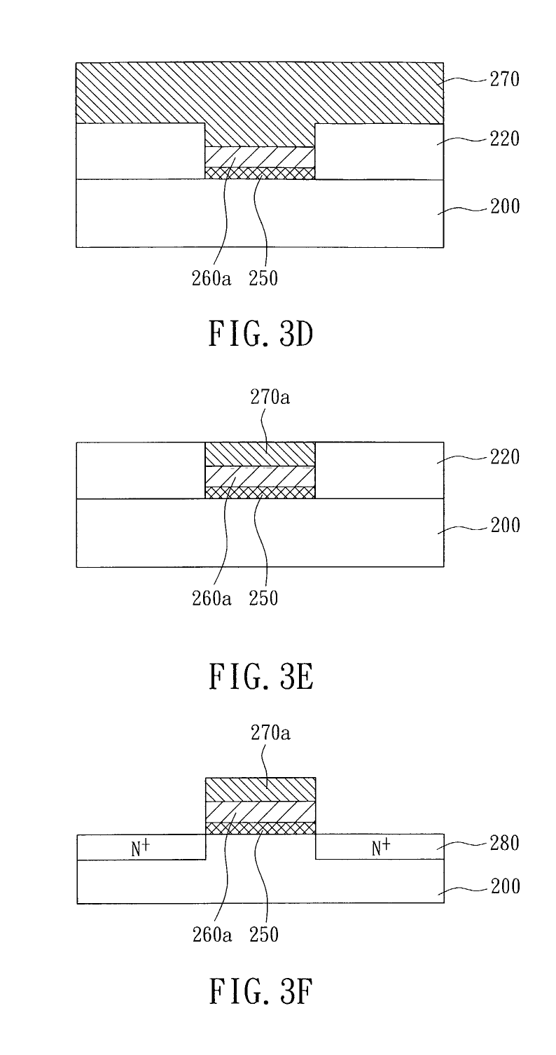

Please refer to FIG. 3A, wherein there is provided a p-type silicon substrate 200. On the p-type silicon substrate 200, a first dielectric layer 220 of 1000˜3500 Å in thickness is formed of silicon nitride or silicon dioxide by chemical vapor-phase deposition (CVD). Then the first dielectric layer 220 is patterned by lithography and etching so as to form a window 240 of 0.05˜0.5 μm in width.

Later, in FIG. 3B, a gate dielectric layer 250 is formed on the substrate 200 inside the window 240, and a poly-silicon layer 260 is formed to cover the gate dielectric layer 250 and the first dielectric layer 260. The gate dielectric layer 250 is formed of silicon dioxide by thermally oxidizing the silicon substrate 200. Alternatively, the gate dielectric layer 250 is formed by depositing a dielectric layer. Moreover, the poly-silicon layer 260 is formed by chemical vapor-phase deposition (CVD).

Moreover, as shown in FIG. 3C, the poly-silicon layer 260 is etched back after the first dielectric layer 220 is exposed again, leaving poly-silicon 260a in the window 240.

Then, as shown in FIG. 3D, a metal layer 270 is formed to cover the poly-silicon layer 260a and also the first dielectric layer 220 again. The metal layer 270 is formed by depositing one of Cu, TiN, W, Al and an alloy thereof.

Please further refer to FIG. 3E, the metal layer 270 outside the window 240 is removed and the device surface is planarized by using chemical mechanical polishing (CMP), forming a metal/poly-silicon stack gate 270a/260a for a field-effect transistor.

Finally, the first dielectric layer 220 on the substrate 200 is removed by etching and then the n-type dopant is heavily doped into the substrate 200 so as to form heavily doped regions 280, used for forming a source region and a drain region, as shown in FIG. 3F.

In this manner, a recessed field-effect transistor is completed.

[The Fourth Embodiment]

Similarly, the present invention is described with reference to a fourth embodiment wherein a recessed field-effect transistor is formed on an n-type substrate. The present embodiment uses the same symbols as in the third embodiment.

Please refer to FIG. 3A, wherein there is provided a n-type silicon substrate 200. On the n-type silicon substrate 200, a first dielectric layer 220 of 1000˜3500 Å in thickness is formed of silicon nitride or silicon dioxide by chemical vapor-phase deposition (CVD). Then the first dielectric layer 220 is patterned by lithography and etching so as to form a window 240 of 0.05˜0.5 μm in width.

Later, in FIG. 3B, a gate dielectric layer 250 is formed on the substrate 200 inside the window 240, and a poly-silicon layer 260 is formed to cover the gate dielectric layer 250 and the first dielectric layer 260. The gate dielectric layer 250 is formed of silicon dioxide by thermally oxidizing the silicon substrate 200. Alternatively, the gate dielectric layer 250 is formed by depositing a dielectric layer. Moreover, the poly-silicon layer 260 is formed by chemical vapor-phase deposition (CVD).

Moreover, as shown in FIG. 3C, the poly-silicon layer 260 is etched back after the first dielectric layer 220 is exposed again, leaving poly-silicon 260a in the window 240.

Then, as shown in FIG. 3D, a metal layer 270 is formed to cover the poly-silicon layer 260a and also the first dielectric layer 220 again. The metal layer 270 is formed by depositing one of Cu, TiN, W, Al and an alloy thereof.

Please further refer to FIG. 3E, the metal layer 270 outside the window 240 is removed and the device surface is planarized by using chemical mechanical polishing (CMP), forming a metal/poly-silicon stack gate 270a/260a for a field-effect transistor.

Finally, the first dielectric layer 220 on the substrate 200 is removed by etching and then the p-type dopant is heavily doped into the substrate 200 so as to form heavily doped regions 280, used for forming a source region and a drain region, as shown in FIG. 3F.

In this manner, a recessed field-effect transistor is completed.

As discussed so far, in accordance with the present invention, there is provided a method for fabricating a recessed field-effect transistor having a stack gate electrode so as to achieve a better work function. Consequently, the present invention has been examined to be progressive and has great potential in commercial applications.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A method for fabricating a recessed field-effect transistor, comprising steps of:
providing a p-type silicon substrate;
forming a first dielectric layer on said substrate;
patterning said first dielectric layer so as to form a window;
forming a gate dielectric layer on said substrate inside said window;
forming a poly-silicon layer covering said gate dielectric layer and said first dielectric layer;
etching back said poly-silicon layer after said first dielectric layer is exposed, leaving poly-silicon in said window;
forming a metal layer covering said poly-silicon layer and said first dielectric layer; removing said metal layer outside said window;
removing said first dielectric layer on said substrate; and
heavily doping n-type ions so as to form heavily doped regions.

2. The method for fabricating a recessed field-effect transistor as recited in claim 1, wherein said first dielectric layer is 1000˜3500 Å in thickness.

3. The method for fabricating a recessed field-effect transistor as recited in claim 2, wherein said first dielectric layer is formed of silicon nitride by deposition.

4. The method for fabricating a recessed field-effect transistor as recited in claim 2, wherein said first dielectric layer is formed of silicon dioxide by deposition.

5. The method for fabricating a recessed field-effect transistor as recited in claim 1, wherein said window is formed by using photolithography and etching to be 0.05˜0.5 μm in width.

6. The method for fabricating a recessed field-effect transistor as recited in claim 1, wherein said gate dielectric layer is formed of silicon dioxide by thermally oxidizing said silicon substrate.

7. The method for fabricating a recessed field-effect transistor as recited in claim 1, wherein said gate dielectric layer is formed by depositing a dielectric layer.

8. The method for fabricating a recessed field-effect transistor as recited in claim 1, wherein said poly-silicon layer is formed by deposition.

9. The method for fabricating a recessed field-effect transistor as recited in claim 1, wherein said metal layer is formed by depositing one of Cu, TiN, W, Al and an alloy thereof.

10. The method for fabricating a recessed field-effect transistor as recited in claim 1, wherein said step of removing said metal layer outside said window is performed by using chemical mechanical polishing (CMP).

11. The method for fabricating a recessed field-effect transistor as recited in claim 1, wherein said heavily doped regions are used for forming a source region and a drain region.

12. A method for fabricating a recessed field-effect transistor, comprising steps of:
providing an n-type silicon substrate;
forming a first dielectric layer on said substrate;
patterning said first dielectric layer so as to form a window;
forming a gate dielectric layer on said substrate inside said window;
forming a poly-silicon layer covering said gate dielectric layer and said first dielectric layer;
etching back said poly-silicon layer after said first dielectric layer is exposed, leaving poly-silicon in said window;
forming a metal layer covering said poly-silicon layer and said first dielectric layer;
removing said metal layer outside said window;
removing said first dielectric layer on said substrate; and
heavily doping p-type ions so as to form heavily doped regions.

13. The method for fabricating a recessed field-effect transistor as recited in claim 12, wherein said first dielectric layer is 1000˜3500 Å in thickness.

14. The method for fabricating a recessed field-effect transistor as recited in claim 13, wherein said first dielectric layer is formed of silicon nitride by deposition.

15. The method for fabricating a recessed field-effect transistor as recited in claim 13, wherein said first dielectric layer is formed of silicon dioxide by deposition.

16. The method for fabricating a recessed field-effect transistor as recited in claim 12, wherein said window is formed by using photolithography and etching to be 0.05˜0.5 μm in width.

17. The method for fabricating a recessed field-effect transistor as recited in claim 12, wherein said gate dielectric layer is formed of silicon dioxide by thermally oxidizing said silicon substrate.

18. The method for fabricating a recessed field-effect transistor as recited in claim 12, wherein said gate dielectric layer is formed by depositing a dielectric layer.

19. The method for fabricating a recessed field-effect transistor as recited in claim 12, wherein said poly-silicon layer is formed by deposition.

20. The method for fabricating a recessed field-effect transistor as recited in claim 12, wherein said metal layer is formed by depositing one of Cu, TiN, W, Al and an alloy thereof.

21. The method for fabricating a recessed field-effect transistor as recited in claim 12, wherein said step of removing said metal layer outside said window is performed by using chemical mechanical polishing (CMP).

22. The method for fabricating a recessed field-effect transistor as recited in claim 12, wherein said heavily doped regions are used for forming a source region and a drain region.
